(19) United States
(12) Patent Application Publication
(10) Pub. No.: US 2005/0156258 A1
(43) Pub. Date: Jul. 21, 2005

(54) Method of forming silicide film having excellent thermal stability, semiconductor device and semiconductor memory device comprising silicide film formed of the same, and methods of manufacturing the semiconductor device and the semiconductor memory device

(75) Inventors: Yun-chang Park, Gyeonggi-do (KR); Chel-jong Choi, Gyeonggi-do (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Gyeonggi-do (KR)

(21) Appl. No.: 11/000,392

(22) Filed: Dec. 1, 2004

(30) Foreign Application Priority Data
Dec. 1, 2003 (KR) 2003-86509

(51) Int. Cl. H01L 21/00; H01L 31/113; C30B 1/00

(52) U.S. Cl. 257/412; 438/238; 438/3; 257/388

(57) ABSTRACT

Provided are a method of forming a silicide film having excellent thermal stability, a semiconductor device and a semiconductor memory device comprising the silicide film formed using the same, and methods of manufacturing the semiconductor device and the semiconductor memory device. A method of forming a nickel mono silicide film including germanium includes sequentially forming a germanium film and a nickel film on a substrate containing silicon and annealing the product. A semiconductor device comprising the nickel mono silicide film, a semiconductor memory device comprising the nickel mono silicide film, and methods of manufacturing the semiconductor device and the semiconductor memory device.

Priority is claimed to Korean Patent Application No. 2003-86509, filed on Dec. 1, 2003, in the Korean Intellectual Property Office, the disclosure of which is incorporated herein in its entirety by reference.

### BACKGROUND OF THE INVENTION

1. Field of the Invention

The present invention relates to a method of forming a material film, and more particularly, to a method of forming a silicide film having excellent thermal stability, a semiconductor device and a semiconductor memory device comprising the silicide film formed using the same, and methods of manufacturing the semiconductor device and the semiconductor memory device.

2. Description of the Related Art

As the integrity of semiconductor devices increases, the size of semiconductor devices such as metal oxide semiconductor field effect transistors (MOSFET) or capacitors decreases below the micron range.

As the size of a semiconductor device becomes smaller than the micron range, the parasitic resistance of the contact region of the semiconductor device, for example, the parasitic resistances of the contact region of the gate, the source, and the drain of MOSFET, increase. As the parasitic resistance increases, RC delay increases, thereby lowering the speed of the semiconductor device.

To solve these problems, a silicide film, which is a reactive product of silicon (Si) and metal, is formed on a contact region to lower a surface resistance and a contact resistance of the contact region.

A titanium silicide (TiSi₂) layer and a cobalt silicide (CoSi₂) layer have been used widely. These two silicide layers have a low specific resistance that is appropriate for the high-speed operation of a semiconductor device.

However, the titanium silicide layer and the cobalt silicide layer have the following defects. The titanium silicide layer generates shorts caused by bridging, and shows a narrow line effect. Accordingly, it is difficult to apply the titanium silicide layer to a semiconductor device. The cobalt silicide layer, although it has better characteristics than the titanium silicide layer, requires a lot of silicon to be formed. It may be difficult to apply the cobalt silicide layer to a semiconductor device having a shallow junction.

Due to such problems of the titanium silicide layer and the cobalt silicide layer, a new silicide layer such as a nickel mono silicide (NiSi) layer has been developed. The nickel mono silicide layer has specific resistance (14 μΩ•cm) similar to that of the titanium silicide and the cobalt silicide, but has no bridging problem or narrow line effect. The amount of required silicon is much less than the silicon required for the cobalt silicide.

However, when the nickel mono silicide is used in the manufacturing process of a semiconductor device, the following problems arise.

In the manufacturing process of a semiconductor device, an annealing process for reflow is performed after an interlayer dielectric such as a BPSG (borophosphosilicate glass) film is formed. The annealing process is performed at a temperature higher than 700° C., which is much higher than temperature required for the formation of the nickel mono silicide. During the annealing process, since the nickel mono silicide is converted into NiSi₂ which has a high specific resistance, the parasitic resistance of a semiconductor device is increased, thereby deteriorating the performance of the semiconductor device.

### SUMMARY OF THE INVENTION

The present invention provides a semiconductor device comprising a silicide film on which sheet resistance is low and thermal stability is excellent.

The present invention also provides a semiconductor memory device including the semiconductor device.

The present invention also provides a method of manufacturing the silicide film used in the semiconductor memory device including the semiconductor device.

The present invention also provides a method of manufacturing the semiconductor device.

The present invention also provides a method of manufacturing the semiconductor memory device.

According to an aspect of the present invention, there is provided a transistor comprising a substrate containing silicon and including a source, a drain, and a gate disposed on the substrate between the source and the drain, wherein a nickel mono silicide (NiSi) film including germanium is formed on at least one of the upper surfaces of the source, the drain, and the gate.

According to another aspect of the present invention, there is provided a semiconductor memory device comprising a transistor, a capacitor connected to the transistor, and a nickel silicide film including germanium interposed between the transistor and the capacitor.

The semiconductor memory device may comprise a conductive plug connecting a drain of the transistor and a lower electrode of the capacitor, wherein the upper surface of the conductive plug is the nickel silicide film including germanium.

The surface layer of the drain may the nickel silicide film including germanium.

According to still anther aspect of the present invention, there is provided a magnetic memory device comprising a transistor, a magnetic resistant, and a nickel silicide film including germanium interposed between the transistor and the magnetic resistant.

The magnetic resistant may be a Magnetic Tunneling Junction cell.

According to an aspect of the present invention, there is provided a method of forming a silicide film, comprising the steps of forming a temporary film that can be absorbed in a reaction between silicon and a metal on a substrate containing silicon, forming a metal film that can react with the silicon in a subsequent annealing process on the temporary film, and forming a metal silicide film on the upper surface layer of the substrate by annealing the substrate on which the metal film and the temporary film are formed.

The temporary film may be a germanium film.

The metal film may be a nickel film.

The substrate may be one selected from the group consisting of a single crystal silicon substrate, a poly-silicon substrate, a doped silicon substrate, an amorphous silicon substrate, a silicon germanium substrate, a silicon nitride substrate and a silicon carbide substrate.

The annealing the product may comprise performing for several tens of seconds under a nitrogen gas atmosphere at a temperature of 300-1000° C. using RTA.

After forming the metal silicide film, the metal film may be removed.

The germanium film may be formed to a thickness of 2-10 nm and the metal film may be a nickel film.

According to another aspect of the present invention, there is provided a method of forming a transistor, comprising the steps of forming a gate stack including a gate insulating film and a gate electrode on a substrate containing silicon, forming a shallow impurity layer on the substrate adjacent to the gate stack, forming gate spacers on both sides of the gate stack, forming a deep impurity layer in the shallow impurity layer adjacent to the gate spacers to form a source and a drain which are composed of the shallow impurity layer and the deep impurity layer, and forming a nickel silicide film including germanium on at least one of the surfaces of the source, the drain, and the gate electrode.

The forming the nickel silicide film may further comprise forming a germanium film that covers the source, the drain, and the gate stack and is absorbed in a reaction between the silicone and a metal on the substrate, forming a nickel film on the germanium film, and annealing the resultant product where the nickel film is formed.

The resultant product may be annealed for several tens of seconds under the nitrogen gas atmosphere at a temperature of 300-1000° C. using RTA.

A portion of the nickel film that remains after annealing the resultant product may be removed.

The substrate may be one selected from the group consisting of a single crystal silicon substrate, a poly-silicon substrate, a doped silicon substrate, an amorphous silicon substrate, a silicon germanium substrate, a silicon nitride substrate and a silicon carbide substrate.

According to an aspect of the present invention, there is provided a method of manufacturing a semiconductor memory device, comprising forming a transistor on a substrate containing silicon, forming an interlayer insulating layer that covers the transistor on the substrate, forming a contact hole exposing a part of the transistor in the interlayer insulating layer, filling the contact hole with a conductive plug, transforming the surface layer of the conductive plug into a silicide film having better thermal stability than TiSi, CoSi, and NiSi, and forming a data storage unit that contacts the silicide film on the interlayer insulating layer.

A silicide film having better thermal stability than that of TiSi, CoSi, and NiSi may be formed on a part of the transistor to be exposed through the contact hole before the forming the interlayer insulating layer.

The substrate may be one selected from the group consisting of a single crystal silicon substrate, a poly-silicon substrate, a doped silicon substrate, an amorphous silicon substrate, a silicon germanium substrate, a silicon nitride substrate and a silicon carbide substrate.

The data storage unit may be one of a capacitor and a MTJ cell.

The silicide film may be formed with a nickel silicide film including germanium.

The forming the nickel silicide film including the germanium may further comprise forming a germanium film that can be absorbed into the nickel silicide film including germanium on a lower material film where the nickel silicide film including germanium is to be formed, forming a nickel film on the germanium film, annealing the resultant product where the nickel film is formed, and removing a remaining portion of the nickel film.

The resultant product may be annealed for several tens of seconds under a nitrogen gas atmosphere at a temperature of 300-1000° C. using RTA.

The silicide film may be a nickel silicide film including germanium.

Use of the foregoing embodiments of the present invention makes it possible to manufacture a silicide film whose thermal stability is higher than the thermal stabilities of TiSi, CoSi, and NiSi. Such a silicide film is applied to a semiconductor device, a semiconductor memory device, etc., resulting in decreased parasitic resistances of the device and thus improving operating characteristics thereof.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are sectional views illustrating a method of forming a silicide film according to an embodiment of the present invention;

FIG. 3 is a graph illustrating variation of free energy when a NiSi film according to the prior art is changed to a NiSi2 film;

FIG. 4 is a graph illustrating variation of free energy when a NiSi film formed using a method of forming a silicide film according to an embodiment of the present invention is changed to a NiSi2 film;

FIG. 5 is a graph illustrating the sheet resistances of silicide films according to annealing temperatures in methods of forming a silicide film according to an embodiment of the present invention and the prior art;

FIG. 6 is a graph illustrating X-ray diffraction analysis results with respect to the nickel silicide film formed using a method of forming a silicide film according to the prior art;

FIG. 7 is a graph illustrating X-ray diffraction analysis results with respect to the nickel silicide film formed using germanium (Ge) film with a thickness of 2 nm in a method of forming a silicide film according to an embodiment of the present invention;

FIG. 8 is a graph illustrating X-ray diffraction analysis results with respect to the nickel silicide film formed using a germanium (Ge) film with a thickness of 5 nm in a method of forming a silicide film according to an embodiment of the present invention;

FIG. 9 is a photo of a transmission electron microscopy with respect to the nickel silicide film formed using s nickel (Ni) film with a thickness of 30 nm according to the prior art;

FIG. 10 is a transmission electron microscopy photo of a nickel silicide film formed using a germanium (Ge) film with a thickness of 2 nm in a method of forming a silicide film according to an embodiment of the present invention;

FIG. 11 is a transmission electron microscopy photo of a nickel silicide film formed using a germanium (Ge) film with a thickness of 5 nm in a method of forming a silicide film according to an embodiment of the present invention;

FIG. 12 is a scanning transmission electron microscopy (STEM) photo of a nickel silicide film formed using a germanium (Ge) film with a thickness of 5 nm in a method of forming a silicide film according to an embodiment of the present invention;

FIG. 13 is an energy dispersive x-ray spectroscopy (EDXs) profile illustrating distribution of components of a nickel silicide film formed using a germanium (Ge) film with a thickness of 5 nm in a method of forming a silicide film according to an embodiment of the present invention;

FIG. 14 is a scanning transmission electron microscopy photo of a nickel silicide film formed using a germanium (Ge) film with a thickness of 2 nm in a method of forming a silicide film according to an embodiment of the present invention;

FIG. 15 is an energy dispersive x-ray spectroscopy (EDXs) profile illustrating distribution of components of a nickel silicide film formed using a germanium (Ge) film with a thickness of 2 nm in a method of forming a silicide film according to one embodiment of the present invention;

FIG. 16 is a graph illustrating sheet resistances of nickel silicide films formed using germanium (Ge) films with thicknesses of 2 nm and 5 nm according to a sequential annealing temperature in methods of forming a silicide film according to an embodiment of the present invention and according to the prior art;

FIGS. 17 through 20 are sectional views illustrating a method of manufacturing a transistor using a method of forming a silicide film according to an embodiment of the present invention; and

FIG. 21 is a sectional view illustrating a semiconductor memory device comprising the silicide film formed using a method of forming a silicide film according to an embodiment of the present invention.

### DETAILED DESCRIPTION OF THE INVENTION

The present invention will now be described more fully with reference to the accompanying drawings. In the drawings, the thicknesses of layers and regions are exaggerated for clarity.

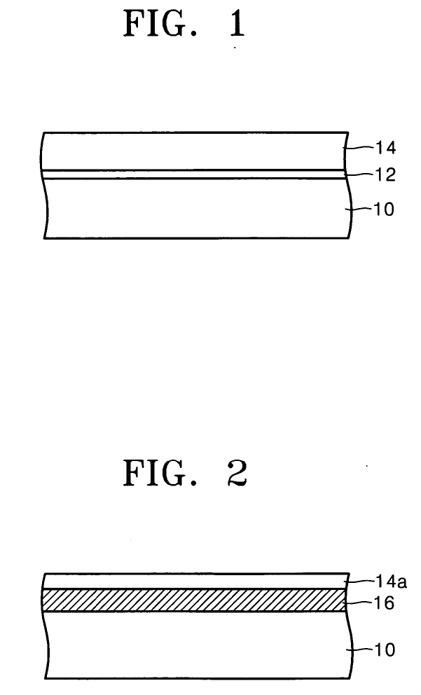

A method of forming a silicide film according to an embodiment of the present invention will now be described with reference to FIGS. 1 and 2.

Referring to FIG. 1, a temporary film 12 is formed on a substrate 10. The temporary film 12 is absorbed into a silicide film while a subsequent silicide film is formed. Accordingly, the temporary film 12 disappears after the silicide film is formed. Alternatively, the temporary film 12 may remain even after the silicide film is formed, but its thickness decreases. A metal film 14 that forms silicide on the temporary film 12 is continuously formed after the temporary film 12, for a time. The substrate 10 and the metal film 14 react with each other during a subsequent annealing process to form a metal compound, i.e. the above-mentioned silicide film. In the process, the temporary film 12 partially or completely is absorbed into the silicide film, which increases the thermal stability of the silicide film. Therefore, it is preferable that the temporary film 12 be formed of a material film which will fuse well with the silicide film. The substrate 10 may be a substrate including silicon, such as a single crystal silicon substrate, a poly-silicon substrate, a doped silicon substrate, an amorphous silicon substrate, a silicon germanium (SiₓGₑ₁₋ₓ) substrate, a silicon nitride (SiₓN₁₋ₓ) substrate or a silicon carbide (SiC) substrate. The metal film 14 may be formed with a nickel film with a predetermined thickness. A material constituting the temporary film 12 may vary according to materials constituting the substrate 10 and the metal film 14. As described above, when the substrate 10 is a substrate including silicon, and the metal film 14 is a nickel film, the temporary film 12 may be a germanium (Ge) film with a predetermined thickness. The thickness of the temporary film 12 may differ according to a field to which the method of forming a silicide film according to the present invention is adapted. When the temporary film 12 is a nickel film, the thickness of the temporary film 12 can be more than 1 nm. Preferably, the temporary film 12 may be formed to about 2-10 nm.

The temporary film 12 and the metal film 14 may be formed using an e-beam evaporator. Also, a CVD, a PVD, a MOCVD, a MBE, or a sputtering method may be used since these methods allow for the easy control of thickness.

As described above, the temporary film 12 and the metal film 14 are sequentially formed on the substrate 10, and then the product is heated for a predetermined time at a predetermined temperature. For example, when the temporary film 12 is a germanium film with a thickness of 2-10 nm, and the metal film 14 is a nickel film with a thickness of about 30 nm, the product comprising sequentially stacked the temporary film 12 and the metal film 14 is annealed using rapid thermal annealing (RTA) for 30 seconds under a nitrogen gas atmosphere at a temperature of 300-1000° C. In this process, a component of the metal film 14 and a component of the substrate 10 react with each other to form a silicide film 16 that includes the component of the metal film 14 and the component of the substrate 10 on the substrate 10, as shown in FIG. 2. In the process of forming the silicide film 16, a component of the temporary film 12 is diffused into the silicide film 16, so that the silicide film 16 includes the component of the temporary film 12. Accordingly, while the formation of the silicide film 16 is completed, the temporary film 12 disappears.

However, part of the temporary film 12 may remain after the formation of the silicide film 16 is completed, although, the temporary film 12 is mostly absorbed into the silicide film 16 in the formation of the silicide film 16. Hence, the thickness of the remaining temporary film 12 is quite a bit less than that of the original temporary film 12 formed, and the remaining temporary film 12 is inconsequential. The characteristics of the silicide film 16 are not influenced by the remaining part of the temporary film 12.

The silicide film 16 may be a nickel mono silicide (NiSi) film. The metal film 14 can be completely exhausted in the process of forming the silicide film 16, or a part 14a of the metal film 14 may remain, as shown in FIG. 2. The remaining metal film 14a on the silicide film 16 can be removed using a predetermined method, e.g., wet etching after the formation of the silicide film 16 is completed.

The silicide film 16 has several important physical properties when the silicide film 16 is a nickel mono silicide film.

As described above, when a nickel film and a germanium film are respectively used as the metal film 14 and the temporary film 12 to form a nickel mono silicide film (hereinafter referred to as NiSi of the present invention), free energy of the nickel mono silicide film is increased than that of a nickel mono silicide formed using a conventional method (hereinafter referred to as NiSi of the prior art).

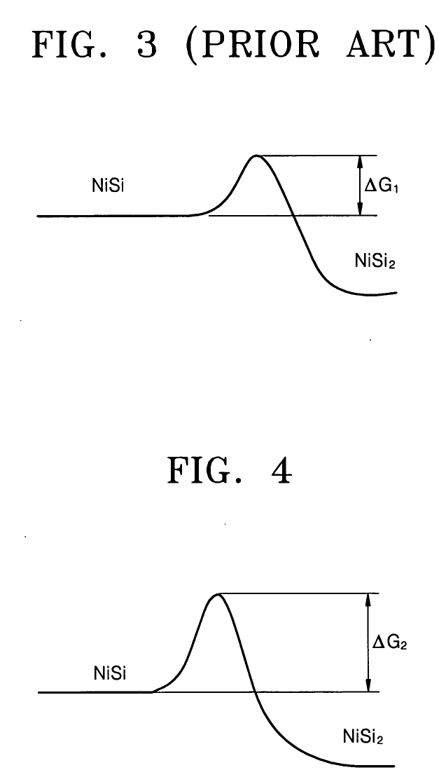

FIGS. 3 and 4 illustrate the respective variations of free energy when the NiSi of the prior art and the NiSi of the present invention are changed to NiSi2. Referring to FIGS. 3 and 4, it can be seen that the variation (ΔG2) of free energy when the NiSi of the present invention is changed to NiSi2 is much larger than the variation (ΔG1) of free energy when the NiSi of the prior art is changed to NiSi2. This shows that the NiSi of the present invention is quite more thermally stable than the NiSi of the prior art.

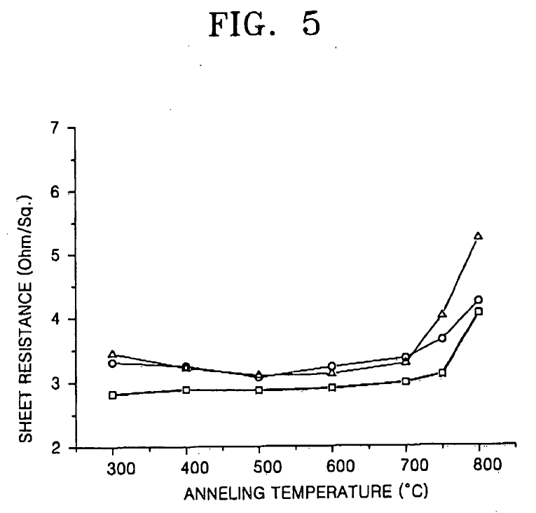

FIG. 5 illustrates sheet resistances of NiSi of the present invention and the NiSi of the prior art. Referring to FIG. 5, it is possible to know the change of each NiSi according to various annealing temperatures when each NiSi is formed. The sheet resistance was measured at 4 points using a sheet resistance measuring instrument. Referring to FIG. 5, the reference symbol Δ denotes the sheet resistance of the NiSi of the prior art using a nickel film with a thickness of 30 nm. The reference symbol □ denotes the sheet resistance of the NiSi of the present invention (hereinafter referred to as the first NiSi) using a germanium film with a thickness of 2 nm and a nickel film with a thickness of 30 nm. The reference symbol ο denotes the sheet resistance of the NiSi of the present invention (hereinafter referred to as the second NiSi) using a germanium film with a thickness of 5 nm and a nickel film with a thickness of 30 nm.

Referring to FIG. 5, the sheet resistance of the NiSi of the prior art remains almost constant up to 700° C. and then rapidly increases at temperatures higher than the 700° C. On the other hand, the sheet resistances of the first NiSi and second NiSi remain almost constant up to 750° C. and gradually increases at temperatures higher than the 750° C.

The results shown in FIG. 5 indicate that with respect to the first NiSi and second NiSi, it is possible to effectively prevent sheet resistance from decreasing according to an increase in the annealing temperature.

With respect to the NiSi of the prior art, the first NiSi, and the second NiSi formed by the annealing process at several temperatures, the results of glancing angle X-ray diffraction (GXRD) will now be described.

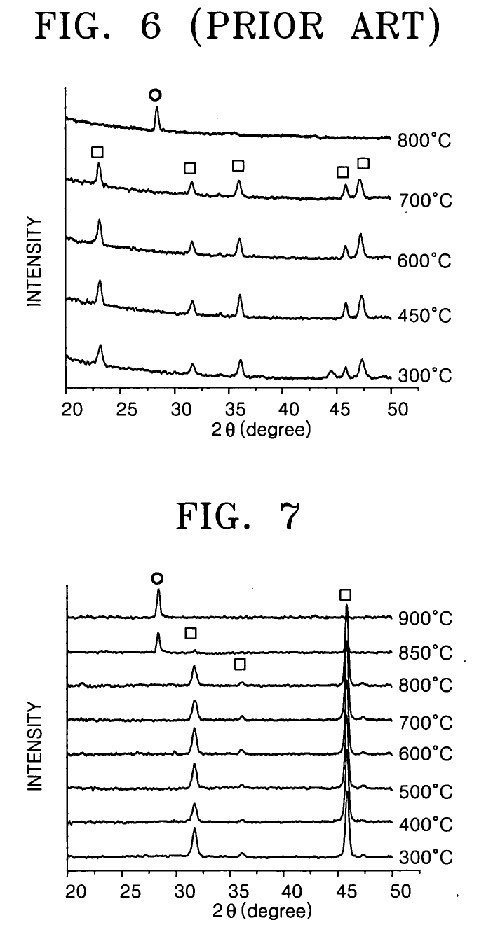

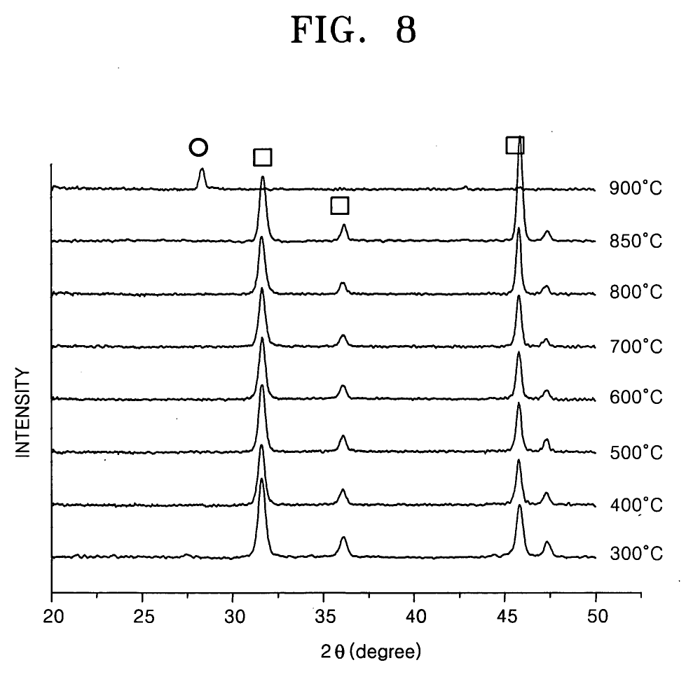

FIG. 6 illustrates GXRD results of the NiSi of the prior art, FIGS. 7 and 8 illustrate the respective GXRD results of the first NiSi and the second NiSi. In FIGS. 6 and 7, the reference symbol □ denotes peaks of NiSi and the reference symbol ο denotes peaks of NiSi₂.

Referring to FIG. 6, it can be seen that with respect to the NiSi of the prior art, only the NiSi exists until the temperature of the RTA reaches 600° C. However, when the temperature of the RTA is higher than 700° C., the NiSi and the NiSi₂ coexist, and, in particular, when the temperature of the RTA is higher than 800° C., only the NiSi₂ exists.

Such a result show that for the NiSi of the prior art, the temperature of formation is 700° C., at which point some of the NiSi is changed to the NiSi₂.

Meanwhile, referring to FIGS. 7 and 8, the GXRD results of the NiSi of the prior art are dramatically different from the GXRD results of the NiSi of the present invention.

To be specific, as shown in FIG. 7, it can be seen that with respect to the first NiSi, only the NiSi exists even when the temperature reaches 800° C., both the Nisi and the NiSi₂ exist when the temperature of formation becomes 850° C., and only the NiSi₂ exists when the temperature reaches 900° C. Such results show that when the temperature of the first NiSi reaches 850° C., some of the first NiSi is changed to the NiSi₂, and when the temperature of the first NiSi reaches 900° C., the first NiSi is completely changed to the NiSi₂.

Referring to FIG. 8, it can be seen that the second NiSi formed using a germanium film with a thickness of 5 nm has a larger range of the temperature of formation than the first NiSi as well as the NiSi of the prior art.

That is, with respect to the second NiSi, only the NiSi exists even when the temperature reaches 850° C., and both the NiSi and the NiSi₂ exist when the temperature reaches 850° C. This means that when the temperature of the second NiSi is 850° C., some of the second NiSi is changed to the NiSi₂.

The results shown in FIGS. 6 through 8 indicate that the temperature at which the NiSi is changed to the NiSi₂ is higher when the NiSi is formed using a germanium film than when the NiSi is not formed using a germanium film. Also, when the NiSi is formed using a germanium film, the thicker the germanium film, the higher the temperature at which the NiSi is changed to the NiSi₂.

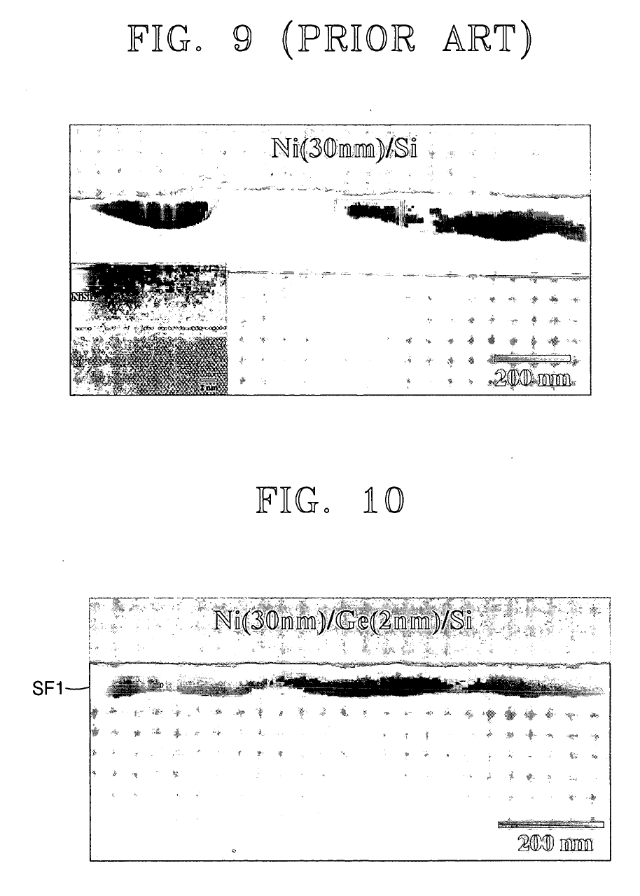

FIGS. 9 through 11 are transmission electron microscopy photos, respectively, illustrating sectional views of the NiSi of the prior art, the first NiSi(SF1), and the second NiSi(SF2), which are formed by the RTA for 30 seconds at a temperature of 700° C.

Referring to FIG. 9, it can be seen that the interface between the NiSi and a Si substrate in the prior art is very rough. A high resolution electron microscopy (HREM) image shown in the lower left of FIG. 9 shows that the NiSi and the NiSi₂ in the prior art coexist. In particular, the part where the NiSi2 exists is deeper than the part where the NiSi exists toward the direction of depth of the substrate. This is because the silicon (Si) consumption is larger when the NiSi₂ is formed than when the NiSi is formed. Therefore, the main reason why a rough interface is formed between the NiSi of the prior art and the substrate may be the formation of the NiSi2.

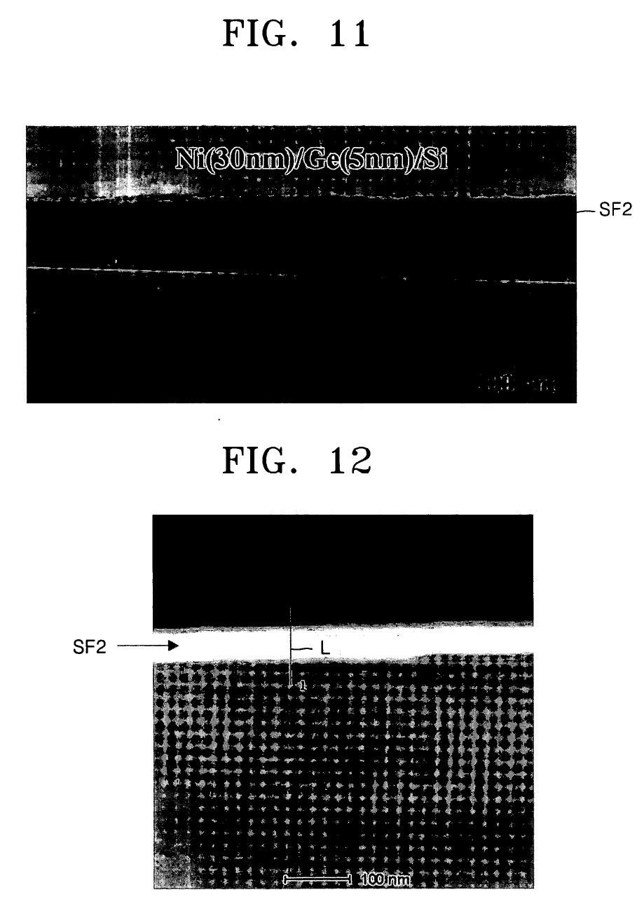

Referring to FIG. 10 illustrating the first NiSi film (SF1) and FIG. 11 illustrating the second NiSi film (SF2), in the first NiSi film (SF1) and the second NiSi film (SF2), the uniformity of the interface between the NiSi and a substrate is much better than that of the prior art shown in FIG. 9.

The results shown in FIGS. 9 through 11 indicate that the uniformity of the interface between the NiSi and the substrate is much better when the NiSi is formed using a germanium film than when the NiSi is not formed using a germanium film.

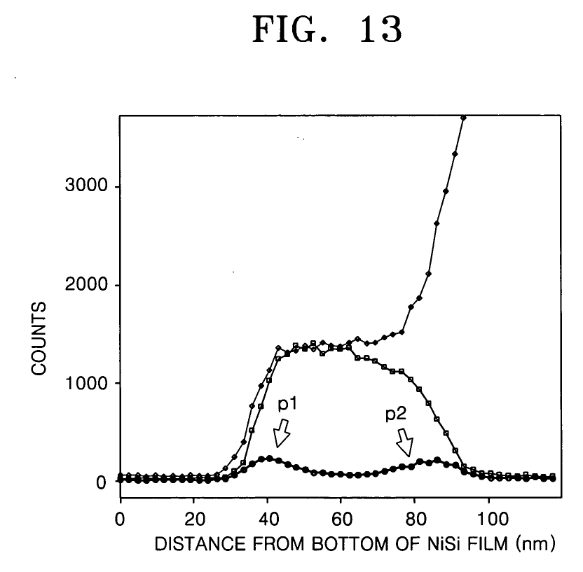

FIG. 12 illustrates Z-contrast image (hereinafter referred to as “STEM image”) produced by scanning transmission electron microscopy (STEM) performed on the second NiSi film (SF2) formed by the RTA for 30 seconds at a temperature of 700° C. FIG. 13 illustrates an energy dispersive x-ray spectroscopy (EDXS) profile measured at several locations of the second NiSi film (SF2). The EDXS profile shown in FIG. 13 is measured from top to bottom along the straight line (L) shown in FIG. 12. Referring to FIG. 13, the reference symbol ∘ denotes the nickel distribution of the second NiSi film (SF2), the reference symbol □ denotes the silicon distribution of the second NiSi film (SF2), the reference symbol ∘ denotes the germanium distribution of the second NiSi film (SF2).

Referring to FIG. 12, the contrast of the second NiSi film (SF2) is constant, which indicates that components of the second NiSi film (SF2) are uniformly distributed throughout the film.

Referring to FIG. 13, germanium is included in the second NiSi film (SF2). The germanium distribution curve (∘) has a first peak p1 corresponding to the surface of the second NiSi film (SF2) and a second peak (p2) corresponding to the interface between the second NiSi film (SF2) and substrate. This indicates that the germanium is uniformly distributed in the second NiSi film (SF2) and that the surface of the second NiSi film (SF2) and the interface between the second NiSi film (SF2) and substrate have a higher concentration of germanium.

Meanwhile, by calculating the concentration of germanium included in the second NiSi film (SF2) from the germanium distribution curve (∘), the germanium of 2.5-3% is uniformly distributed in the second NiSi film (SF2).

Since the germanium is included in the second NiSi film (SF2), the second NiSi film (SF2) can be expressed as NiSi₁₋ₓGeₓ.

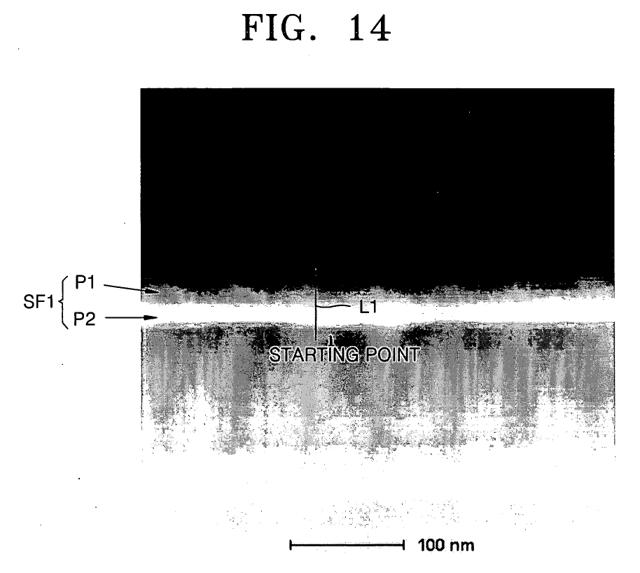

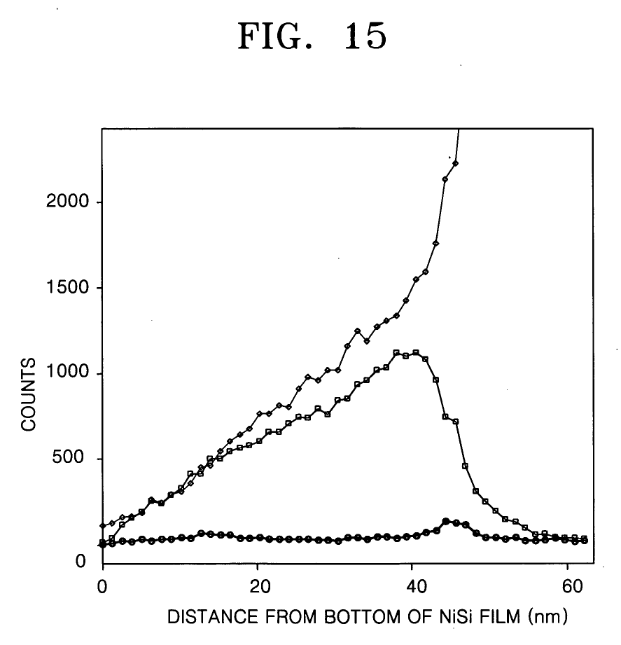

FIG. 14 illustrates a STEM image of the first NiSi film (SF1) formed by the RTA for 30 seconds at a temperature of 700° C. FIG. 15 is an EDXS profile measured at several locations of the first NiSi film (SF1).

The EDXS profile shown in FIG. 15 is measured from top to bottom along the straight line (L1) shown in FIG. 14. Referring to FIG. 15, the reference symbol □ denotes the nickel distribution of the first NiSi film (SF1), the reference symbol [symbol] denotes the silicon distribution of the first NiSi film (SF1), the reference symbol ∘ denotes the germanium distribution of the first NiSi film (SF1).

Referring to FIG. 14, two portions P1 and P2 of the first NiSi film (SF1) have different contrast from each other, which indicates that the first NiSi film (SF1) has two layers having different composition from each other.

The second part P2, which has bright contrast, has a germanium of 2.5%-3%, which can know from quantitative analysis of the EDXS profile shown in FIG. 15, whereas the first part P1, which is relatively dark, has no germanium.

That is, the first part P1, which is an interface between the substrate and the first NiSi film (SF1), has NiSi₁₋ₓGeₓ and the second part P2 has mainly NiSi.

The germanium distribution curve (∘) of FIG. 15 indicates that germanium exists at the surface of the first NiSi film (SF1) and around the interface between the substrate and the first NiSi film (SF1). However, the concentration of the germanium in the first NiSi film (SF1) is much less than in the second NiSi film (SF2).

On the other hand, in an actual process of manufacturing a semiconductor device, an interlayer insulating layer reflow is performed in order to form an interlayer insulating layer after forming a silicide film such as the first NiSi film (SF1) or the second NiSi film (SF2). The reflow process requires annealing process, which takes longer and requires a higher temperature than the process of forming the first NiSi film (SF1) or the second NiSi film (SF2).

In order for a semiconductor device formed with the first NiSi film (SF1) or the second NiSi film (SF2) to have better performance than a semiconductor device formed with the NiSi of the prior art, it needs to secure the thermal stability of the first NiSi film (SF1) and the second NiSi film (SF2) for a subsequent high temperature process such as the reflow process.

Experiments used to test the thermal stability of the first NiSi film (SF1), the second NiSi film (SF2) and the NiSi of the prior art during a subsequent high temperature process will now be described.

First, the NiSi of the prior art, the first NiSi film (SF1), and the second NiSi film (SF2) were formed by RTA for 30 seconds at a temperature of 550° C. After each NiSi film was formed, Ni that had not reacted was removed.

Then, the NiSi of the prior art, the first NiSi film (SF1), and the second NiSi film (SF2) were annealed at four temperatures, 550° C., 600° C., 650° C., and 700° C., each for 30 seconds. The annealing process was performed in a tube furnace under the nitrogen gas atmosphere. Every time the annealing at each temperature was completed, the sheet resistances of the NiSi of the prior art, the first NiSi film (SF1), and the second NiSi film (SF2) were measured.

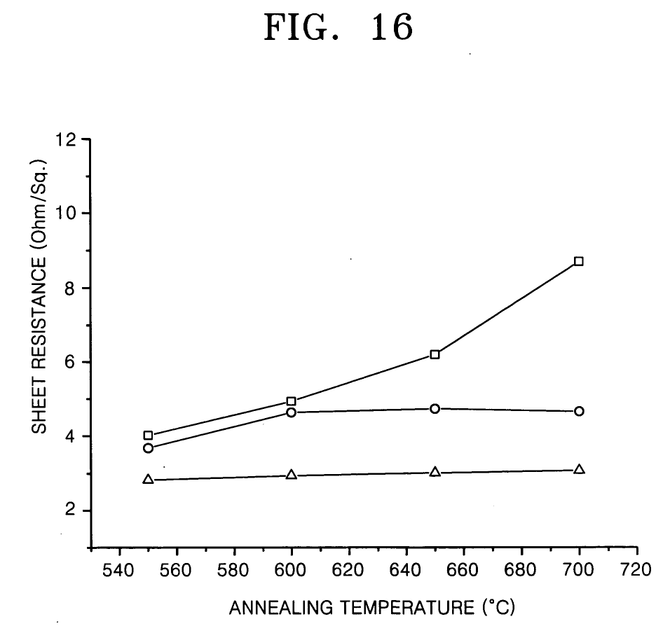

FIG. 16 shows the sheet resistance of the NiSi of the prior art, the first NiSi film (SF1), and the second NiSi film (SF2). Referring to FIG. 16, the reference symbol □ denotes the sheet resistance of the NiSi of the prior art, the reference symbol Δ denotes the sheet resistance of the first NiSi film (SF1), the reference symbol ∘ denotes the sheet resistance of the second NiSi film (SF2).

As the annealing temperatures of the NiSi of the prior art, the first NiSi film (SF1), and the second NiSi film (SF2) increase, the sheet resistance (∘) of the NiSi of the prior art increases, whereas the sheet resistances (Δ, ∘) of the first NiSi film (SF1) and the second NiSi film (SF2) are lower than and increase slower than the sheet resistance (∘) of the NiSi of the prior art. In particular, when the annealing temperature reaches 700° C., the sheet resistance (∘) of the NiSi of the prior art rapidly increases, whereas the sheet resistances (Δ, ∘) of the first NiSi film (SF1) and the second NiSi film (SF2) do not change much.

Such results indicate that the thermal stability of the first NiSi film (SF1) and the second NiSi film (SF2) in the annealing process is much higher than that of the NiSi of the prior art.

Also, in comparison with the thermal stability of the first NiSi film (SF1) and the second NiSi film (SF2) in FIG. 16, the sheet resistance of the first NiSi film (SF1) is lower than that of the second NiSi film (SF2) and thus the first NiSi film (SF1) is more thermally stable than the second NiSi film (SF2). This indicates that the thinner the germanium film, the higher the thermal stability of the NiSi film in the process of forming the NiSi film according to an embodiment of the present invention.

A method of manufacturing a semiconductor device to which the method of forming a silicide film according to an embodiment of the present invention is applied will now be described.

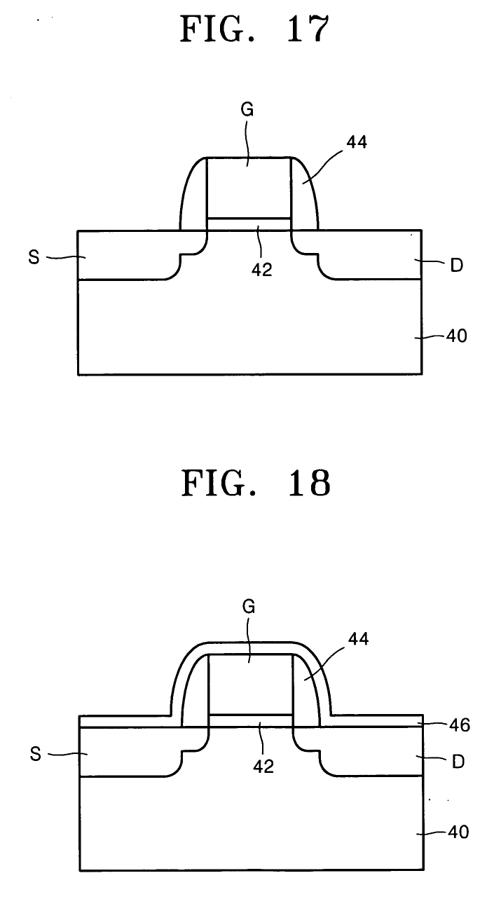

FIGS. 17 through 20 are sectional views illustrating a method of manufacturing MOSFET using the method of forming a silicide film according to an embodiment of the present invention.

Referring to FIG. 17, a substrate 40 including silicon includes an active region and a field region, a device separating film (not shown) is formed on the field region, and a gate laminate including a gate insulating film 42 and a gate electrode G are formed on the active region. The gate laminate is used as a mask to form a shallow conductive impurity layer on the active region of the substrate 40. Gate spacer 44 is formed on the side walls of the gate laminate. The gate laminate and the gate spacers 44 are used as a mask to form a deep conductive impurity layer on the active region of the substrate 40. Hence, a LDD (Lightly Doped Drain) source region S and a LDD type drain region D are formed on the active region of the substrate 40.

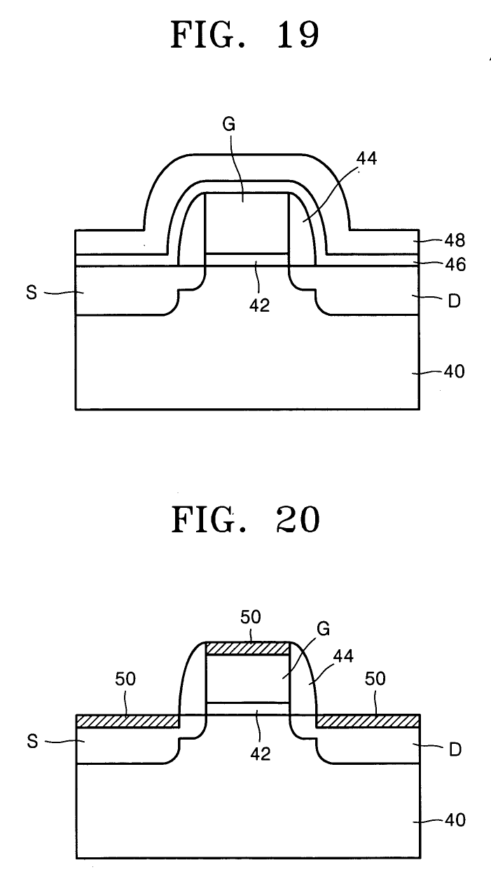

As shown in FIGS. 18 and 19, a germanium film 46 and a nickel film 48 that cover the gate laminate and the gate spacer 44 are sequentially formed on the substrate 40. The germanium film 46 may be formed to a thickness of more than 1 nm, desirably 2-10 nm. The nickel film 48 may be formed to a thickness of 30 nm. However, the thickness of the nickel film 48 can be varied according to the desired thickness of the silicide film. A metal film that reacts with silicon to form a silicide may be formed instead of the nickel film 48. The germanium film 46 may also be replaced with a material film capable of increasing the thermal stability of a reactant of the metal film and the silicon.

The product obtained after the germanium film 46 and the nickel film 48 are sequentially formed is RTA-processed under the same condition as described above. Since the silicide reaction occurs only in a material film including silicon, a nickel silicide reaction selectively occurs in the RTA process in the gate electrode G, the source region S, and the drain region D, where nickel can react with silicon. As shown in FIG. 20, a NiSi film 50 is formed only on the gate electrode G, the source region S, and the drain region D. A portion of the nickel film 48 that remains after the NiSi film 50 is formed is removed by hydroetching. The NiSi film 50 may be one of the first NiSi film (SF1) and the second NiSi film (SF2). Hence, the activation energy, which must be attained for a phase transition of the NiSi film 50 to occur, is higher in the product than for the NiSi film of the prior art. Accordingly, the NiSi film 50 is more thermally stable than the NiSi film of the prior art.

An example in which the method of forming a silicide film according to an embodiment of the present invention is applied to a method of manufacturing a semiconductor memory device will now be described.

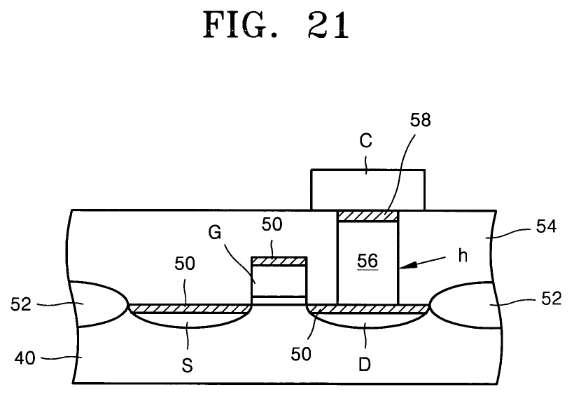

FIG. 21 shows a method of manufacturing a semiconductor memory device including a transistor and a capacitor using the method of forming a silicide film according to an embodiment of the present invention.

Referring to FIG. 21, field oxidation films 52 are formed on predetermined regions of a semiconductor substrate 40. A gate laminate including a gate insulating film 42 and a gate electrode G is formed on the semiconductor substrate 40 between the field oxidation films 52. A source region S and a drain region D are formed on the substrate 40 between the gate laminate and the field oxidation film 52. A NiSi film 50 is formed on the upper surfaces of the source region S, the drain region D, and the gate electrode G using a method of forming a silicide film according to an embodiment of the present invention. An interlayer insulating layer 54 is formed on the product obtained after the NiSi film 50 is formed and a contact hole h exposing the portion of the NiSi film 50 formed on the drain region D is formed in the interlayer insulating layer 54. The interlayer insulating layer 54 may be, e.g., a BPSG film. The contact hole h is filled with a conductive plug 56 and a NiSi film 58 is formed on the upper surface of the conductive plug 56 using a method of forming a silicide film according to an embodiment of the present invention. The conductive plug 56 may extend over the interlayer insulating layer 54. A capacitor C that contacts the upper surface of the NiSi film 58 is formed on the interlayer insulating layer 54. Although not shown in the drawings, a lower electrode of the capacitor C may take on a variety of forms; and may be a simple laminate or have a cylindrical shape. A material film such as a spread preventing film may be further formed between the lower electrode and the NiSi film 58. The dielectric film of the capacitor C may be a ferroelectric film. The upper and lower electrodes of the capacitor C may be formed of various materials that depend on the kind of the dielectric film.

A method of forming a silicide film according to an embodiment of the present invention may be applied to a memory device other than the semiconductor memory device as shown in FIG. 21. For example, a NiSi film containing germanium Ge can be formed on the contact surface of a transistor, which is a switching device, or a magnetic resistant, e.g. a MTJ (Magnetic Tunneling Junction), cell in a method of manufacturing a magnetic random access memory (MRAM) according to an embodiment of the present invention.

As described above, in a method of forming a silicide film according to an embodiment of the present invention, a Ge film is interposed between a Ni film and a substrate including silicon to form a NiSi film during an annealing process. A semiconductor device having a low sheet resistance and excellent thermal stability can be manufactured using the NiSi film. When the method of forming a silicide film is applied to a semiconductor device, a semiconductor memory device, or a next-generation device, a device with high quality can be effectively manufactured and the performance of the device can be maximized to improve competitiveness of the goods.

While the present invention has been particularly shown and described with reference to exemplary embodiments thereof, the thickness of the NiSi film according to the location where the NiSi film is formed and the thickness of the germanium film can be varied by a person skilled in the art. The method of forming a silicide film may be applied to a method of manufacturing a transistor other than MOSFET. Therefore, various changes in form and details may be made to the description herein without departing from the spirit and scope of the present invention as defined by the following claims.

1. A transistor comprising:
a substrate containing silicon and including a source and a drain; and
a gate disposed on the substrate between the source and the drain,
wherein a nickel mono silicide (NiSi) film including germanium is formed on at least one of the upper surfaces of the source, the drain, and the gate.

2. A semiconductor memory device, comprising:
a transistor;
a capacitor connected to the transistor; and
a nickel silicide film including germanium interposed between the transistor and the capacitor.

3. The semiconductor memory device of claim 2, further comprising a conductive plug connecting a drain of the transistor and a lower electrode of the capacitor, wherein the upper surface of the conductive plug is the nickel silicide film including germanium.

4. The semiconductor memory device of claim 3, wherein the surface layer of the drain is the nickel silicide film including germanium.

5. A magnetic memory device, comprising a transistor, a magnetic resistant, and a nickel silicide film including germanium interposed between the transistor and the magnetic resistant.

6. The magnetic memory device of claim 3, the magnetic resistant is a Magnetic Tunneling Junction cell.

7. A method of forming a silicide film, comprising:
forming a temporary film that can be absorbed in a reaction between silicon and a metal on a substrate containing silicon;
forming a metal film that can react with the silicon in a subsequent annealing process on the temporary film;
forming a metal silicide film on the upper surface layer of the substrate by annealing the substrate on which the metal film and the temporary film are formed.

8. The method of forming a silicide film of claim 7, wherein the temporary film is a germanium film.

9. The method of forming a silicide film of claim 7, wherein the metal film is a nickel film.

10. The method of forming a silicide film of claim 7, wherein the substrate is one selected from the group consisting of a single crystal silicon substrate, a poly-silicon substrate, a doped silicon substrate, an amorphous silicon substrate, a silicon germanium substrate, a silicon nitride substrate and a silicon carbide substrate.

11. The method of forming a silicide film of claim 7, wherein the annealing the product comprises performing for several tens of seconds under a nitrogen gas atmosphere at a temperature of 300-1000° C. using RTA.

12. The method of forming a silicide film of claim 7, after forming the metal silicide film, the metal film is removed.

13. The method of forming a silicide film of claim 8, wherein the germanium film is formed to a thickness of 2-10 nm.

14. The method of forming a silicide film of claim 8, wherein the metal film is a nickel film.

15. A method of forming a transistor, comprising:
forming a gate stack including a gate insulating film and a gate electrode on a substrate containing silicon;
forming a shallow impurity layer on the substrate adjacent to the gate stack;
forming gate spacers on both sides of the gate stack;
forming a deep impurity layer in the shallow impurity layer adjacent to the gate spacers to form a source and a drain which are composed of the shallow impurity layer and the deep impurity layer; and
forming a nickel silicide film including germanium on at least one of the surfaces of the source, the drain, and the gate electrode.

16. The method of forming a transistor of claim 15, wherein the forming the nickel silicide film comprises:
forming a germanium film that covers the source, the drain, and the gate stack and is absorbed in a reaction between the silicone and a metal on the substrate;
forming a nickel film on the germanium film; and
annealing the resultant product where the nickel film is formed.

17. The method of forming a transistor of claim 15, wherein the substrate is one selected from the group consisting of a single crystal silicon substrate, a poly-silicon substrate, a doped silicon substrate, an amorphous silicon substrate, a silicon germanium substrate, a silicon nitride substrate and a silicon carbide substrate.

18. The method of forming a transistor of claim 16, wherein the resultant product is annealed for several tens of seconds under the nitrogen gas atmosphere at a temperature of 300-1000° C. using RTA.

19. The method of forming a silicide film of claim 16, wherein a portion of the nickel film that remains after annealing the resultant product is removed.

20. The method of forming a transistor of claim 16, wherein the substrate is one selected from the group consisting of a single crystal silicon substrate, a poly-silicon substrate, a doped silicon substrate, an amorphous silicon substrate, a silicon germanium substrate, a silicon nitride substrate and a silicon carbide substrate.

21. A method of manufacturing a semiconductor memory device, comprising:
forming a transistor on a substrate containing silicon;
forming an interlayer insulating layer that covers the transistor on the substrate;
forming a contact hole exposing a part of the transistor in the interlayer insulating layer;
filling the contact hole with a conductive plug;
transforming the surface layer of the conductive plug into a silicide film having better thermal stability than TiSi, CoSi, and NiSi; and
forming a data storage unit that contacts the silicide film on the interlayer insulating layer.

22. The method of manufacturing a semiconductor memory device of claim 21, wherein a silicide film having better thermal stability than that of TiSi, CoSi, and NiSi is formed on a part of the transistor to be exposed through the contact hole before the forming the interlayer insulating layer.

23. The method of manufacturing a semiconductor memory device of claim 21, wherein the substrate is one selected from the group consisting of a single crystal silicon substrate, a poly-silicon substrate, a doped silicon substrate, an amorphous silicon substrate, a silicon germanium substrate, a silicon nitride substrate and a silicon carbide substrate.

24. The method of manufacturing a semiconductor memory device of claim 21, wherein the data storage unit is one of a capacitor and a MTJ cell.

25. The method of manufacturing a semiconductor memory device of claim 21, wherein the silicide film is formed with a nickel silicide film including germanium.

26. The method of manufacturing a semiconductor memory device of claim 25, wherein the forming the nickel silicide film including the germanium comprises:
forming a germanium film that can be absorbed into the nickel silicide film including germanium on a lower material film where the nickel silicide film including germanium is to be formed;
forming a nickel film on the germanium film;
annealing the resultant product where the nickel film is formed; and
removing a remaining portion of the nickel film.

27. The method of manufacturing a semiconductor memory device of claim 26, wherein the resultant product is annealed for several tens of seconds under a nitrogen gas atmosphere at a temperature of 300-1000° C. using RTA.

28. The method of manufacturing a semiconductor memory device of claim 22, wherein the silicide film is a nickel silicide film including germanium.
